(19) United States
(12) Patent Application Publication
(10) Pub. No.: US 2026/0022009 A1
(43) Pub. Date: Jan. 22, 2026

(54) Gamepad Microphone

(71) Applicant: Silicon Audio Directional LLC, Austin, TX (US)

(72) Inventors: Neal A. Hall, Austin, TX (US); Xiaoyu Niu, Austin, TX (US)

(21) Appl. No.: 19/274,263

(22) Filed: Jul. 18, 2025

Related U.S. Application Data
(60) Provisional application No. 63/673,606, filed on Jul. 19, 2024.

(51) Int. Cl. B81B 3/00; H04R 1/08; H04R 1/34; H04R 17/02

(52) U.S. Cl. CPC B81B 3/0086; H04R 1/08; H04R 1/342; H04R 17/02; B81B 2201/0257; B81B 2203/0118; B81B 2203/0127; B81B 2203/0307; B81B 2203/0315; B81B 2203/04; B81B 2207/015; B81B 2207/07; H04R 2201/003; H04R 2499/11

(57) ABSTRACT

A microphone can include at least two deformable elements anchored at a center and sharing a common backside cavity. The at least two deformable elements can be deformable under pressure. Vibration modes of the at least two deformable elements can be coupled such that a first vibration mode can be associated with a uniform movement of all deformable elements and a second vibration mode can be associated with out-of-phase movements among the deformable elements. Deformation of each deformable element can be detected via a sensing material in contact with each deformable element to form a sensing port. Thus, the microphone can include at least two sensing ports and signals from the at least two sensing ports can be subtracted using analog or digital electronics to yield a signal responsive primarily to a pressure gradient along an axis.

### PRIORITY INFORMATION

This application claims benefit of priority to U.S. Provisional Application Ser. No. 63/673,606, titled “Gamepad Microphone”, filed Jul. 19, 2024, which is hereby incorporated by reference in its entirety as though fully and completely set forth herein.

### FIELD OF THE INVENTION

This disclosure relates generally to microphones, and more particularly to micro-electro-mechanical systems (MEMS) microphones for use in measuring, for example, pressure and in-plane pressure gradients.

### DESCRIPTION OF THE RELATED ART

Miniature microphones, which may be used in a variety of applications (e.g., defense, cellular telephones, laptop computers, portable consumer electronics, hearing aids), generally include a compliant membrane and a rigid back electrode in close proximity to form a capacitor with a gap. Incoming sound waves induce vibrations in the compliant membrane and these vibrations change the capacitance of the structure which can be sensed with electronics.

Recently, MEMS processing has been utilized to fabricate miniature microphones. Additionally, piezoelectric microphones with in-plane (i.e., x-y plane) directivity were recently introduced. These structures synthesized an innovative, biologically-inspired sensing structure with integrated piezoelectric readout. It is reasoned that A-weighted pressure noise levels approaching 40 dB (A) are achievable from a structure that can be repeated on chip to address both in-plane gradient measurements (i.e., dp/dx, dp/dy). Preliminary directivity measurements illustrated proof-of-concept functionality. However, further improvements in the field are desired.

### SUMMARY OF THE INVENTION

Various embodiments of a microphone are presented herein. The microphone can include multiple deformable elements, e.g., with coupled vibration modes and multiple measurands (e.g., P₀, dp/dx, dp/dy).

For example, in some embodiments, a microphone can include at least two deformable elements anchored at a center (or center region and/or common center region) and sharing a common backside cavity. The at least two deformable elements can be deformable under pressure. The center (or center region/common center region) can be supported by beams etched into a bulk silicon wafer. Vibration modes of the at least two deformable elements can be coupled such that a first vibration mode can be associated with a uniform movement of all deformable elements, e.g., responsive to a uniform pressure, and a second vibration mode can be associated with out-of-phase movements among the deformable elements, e.g., responsive to a pressure gradient. Deformation of each deformable element can be detected via a sensing material (e.g., such as a piezoelectric material) in contact with each deformable element, e.g., to form a sensing port. Thus, the microphone can include at least two sensing ports (e.g., each deformable element can have a corresponding sensing port. Signals from the at least two sensing ports can be subtracted using analog or digital electronics to yield a signal responsive primarily to a pressure gradient along an axis. Further, signals from the at least two sensing ports can be post processed using analog or digital electronics, including arithmetic operations to derive alternative or additional output signals from the microphone. Additionally, signals from the at least two sensing ports can be used as input into a neural network, e.g., to accomplish a particular task, e.g., such as enhancement of a desired signal and/or suppression of non-desired signals, and/or to train the neural network.

As another example, in some embodiments, a microphone package, e.g., suitable for integration into a product, can include a first substrate that houses a microphone die and an Application Specific Integrated Circuit (ASIC). The first substrate can have and/or include a sound inlet. The microphone package can further include a cavity formed by a second substrate and sidewalls. The sound inlet can allow deformable elements to be in contact with and deform under external pressure and pressure gradient from a sound field external to the microphone package. Signals from sensing ports, e.g., formed via a sensing material in contact with the deformable elements can be routed to the ASIC and signals from the ASIC can be routed to the first substrate and/or the second substrate via wiring. Vertical Interconnect Accesses (VIAs) in the first substrate and/or the second substrate can make electrical signals available at an external surface of the microphone package. The deformable elements can be anchored at a center (or center region and/or common center region) and share a common backside cavity. In addition, vibration modes of the deformable elements can be coupled such that a first vibration mode can be associated with a uniform movement of all deformable elements, e.g., responsive to a uniform pressure, and a second vibration mode can be associated with out-of-phase movements among the deformable elements, e.g., responsive to a pressure gradient.

As a further example, in some embodiments, a user equipment device (UE) can include at least one directional microphone, a memory, and a processor in communication with the memory and the one or more direction microphones and configured to digitally processes signals produced from the one at least one directional microphone. The at least one directional microphone at least two deformable elements anchored at a center (or center region and/or common center region) and sharing a common backside cavity. The at least two deformable elements can be deformable under pressure. The center (or center region/common center region) can be supported by beams etched into a bulk silicon wafer. Vibration modes of the at least two deformable elements can be coupled such that a first vibration mode can be associated with a uniform movement of all deformable elements, e.g., responsive to a uniform pressure, and a second vibration mode can be associated with out-of-phase movements among the deformable elements, e.g., responsive to a pressure gradient. Deformation of each deformable element can be detected via a sensing material (e.g., such as a piezoelectric material) in contact with each deformable element, e.g., to form a sensing port. Thus, the microphone can include at least two sensing ports (e.g., each deformable element can have a corresponding sensing port. Signals from the at least two sensing ports can be subtracted using analog or digital electronics to yield a signal responsive primarily to a pressure gradient along an axis. The pressure gradient can include a first gradient along a first axis and a second gradient along a second axis that form a microphone plane along the axis and substantially parallel to an exterior surface of the UE. The microphone plane can be substantially normal to a display of the UE and/or to a plane housing a camera of the UE. In addition, the at least one directional microphone can include circuitry configured to steer a first order directivity pattern using the signals and the microphone plane can substantially parallel to a field of view of a camera of the UE. Additionally, the microphone plane can be offset in a vertical direction substantially perpendicular to the exterior surface.

### BRIEF DESCRIPTION OF THE DRAWINGS

The following detailed description refers to the accompanying drawings, which are now briefly described.

FIGS. 1A-1C illustrate examples of a packaged microphone, according to some embodiments.

FIGS. 2A-2B illustrate an example of a MEMS microphone, according to some embodiments.

FIGS. 2C-2E illustrate examples of mode shapes of a MEMS microphone, according to some embodiments.

FIGS. 3A-3C illustrate another example of a MEMS microphone, according to some embodiments.

FIG. 3D illustrates additional examples of mode shapes of a MEMS microphone, according to some embodiments.

FIGS. 4A-4E illustrate examples of components and assemblies of a microphone package, according to some embodiments.

FIG. 5 illustrates an example of a MEMS microphone, according to some embodiments.

FIGS. 6A-6B illustrate another example of a microphone package, according to some embodiments.

FIGS. 7A-7C illustrate an example of a user equipment device (UE) 700 which can include embodiments of the invention.

FIG. 8 illustrates an example of a user equipment device (UE) 800 which can include embodiments of the invention.

FIGS. 9A-9C and 10 illustrate examples of various configurations of UE with a MEMS microphone, according to some embodiments.

FIG. 11 illustrates an example of steering a MEMS microphone, according to some embodiments.

FIG. 12 illustrates an example block diagram of a wireless device, according to some embodiments.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

The headings used herein are for organizational purposes only and are not meant to be used to limit the scope of the description. As used throughout this application, the word “can” and “may” are used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third component electrically connected to the module substrate” does not preclude scenarios in which a “fourth component electrically connected to the module substrate” is connected prior to the third component, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112(f) for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF THE INVENTION

### Terms

Approximately—refers to a value that is almost correct or exact. For example, approximately may refer to a value that is within 1 to 10 percent of the exact (or desired) value. It should be noted, however, that the actual threshold value (or tolerance) may be application dependent. For example, in one embodiment, “approximately” may mean within 0.1% of some specified or desired value, while in various other embodiments, the threshold may be, for example, 2%, 3%, 5%, and so forth, as desired or as required by the particular application. Furthermore, the term approximately may be used interchangeably with the term substantially. In other words, the terms approximately and substantially are used synonymously to refer to a value, or shape, that is almost correct or exact.

Couple—refers to the combining of two or more elements or parts. The term “couple” is intended to denote the linking of part A to part B, however, the term “couple” does not exclude the use of intervening parts between part A and part B to achieve the coupling of part A to part B. For example, the phrase “part A may be coupled to part B” means that part A and part B may be linked indirectly, e.g., via part C. Thus, part A may be connected to part C and part C may be connected to part B to achieve the coupling of part A to part B.

Functional Unit (or Processing Element)—refers to various elements or combinations of elements. Processing elements include, for example, circuits such as an ASIC (Application Specific Integrated Circuit), portions or circuits of individual processor cores, entire processor cores, individual processors, programmable hardware devices such as a field programmable gate array (FPGA), and/or larger portions of systems that include multiple processors, as well as any combinations thereof.

User Equipment (UE) (or “UE Device”)—any of various types of computer systems or devices that are mobile or portable, and that perform wireless communications. Examples of UE devices include mobile telephones or smart phones (e.g., iPhone™, Android™-based phones), tablet computers, portable gaming devices, laptops, wearable devices (e.g., smart watch, smart glasses, smart goggles, head-mounted display devices, and so forth), portable Internet devices, music players, data storage devices, or other handheld devices, automobiles and/or motor vehicles, unmanned aerial vehicles (UAVs) (e.g., drones), UAV controllers (UACs), etc. In general, the term “UE” or “UE device” can be broadly defined to encompass any electronic, computing, and/or telecommunications device (or combination of devices) which is easily transported by a user and capable of wireless communication.

Wireless Device or Station (STA)—any of various types of computer systems or devices that perform wireless communications. A wireless device can be portable (or mobile) or can be stationary or fixed at a certain location. The terms “station” and “STA” are used similarly. A UE is an example of a wireless device.

Communication Device—any of various types of computer systems or devices that perform communications, where the communications can be wired or wireless. A communication device can be portable (or mobile) or can be stationary or fixed at a certain location. A wireless device is an example of a communication device. A UE is another example of a communication device.

Processing Element (or Processor)—refers to various elements or combinations of elements that are capable of performing a function in a device, e.g., in a communication device or in a network infrastructure device. Processors can include, for example: processors and associated memory, circuits such as an ASIC (Application Specific Integrated Circuit), portions or circuits of individual processor cores, entire processor cores, processor arrays, programmable hardware devices such as a field programmable gate array (FPGA), and/or larger portions of systems that include multiple processors, as well any of various combinations of the above.

Piezoelectric sensor—refers to a sensor that relies on the piezoelectric effect, i.e., the electromechanical interaction between the mechanical and the electrical state in a certain class of materials.

Audio Spectrum—refers to the portion of the frequency spectrum that is audible to humans. In general, audible frequencies range from approximately 20 Hz on the low end to 20,000 Hz on the high end. Thus, the audio spectrum is considered to span from 20 Hz to 20 kHz. In general, the center of the audio spectrum may be considered to be approximately 1 kHz.

### Gamepad Microphone

Traditionally, sound localization has been performed using multiple microphones in a configured array. However, as electronics packaging, e.g., such as cell phones, in-ear headphones, has shrunk, a need to reduce the number of microphones used for sound localization has increased. This need led to research into replicating the hearing capabilities of parasitoid fly, Ormia Ochracea. The research has shown that a new type of localizing microphone can be fabricated. This research led to the development and commercialization of a microphone that had improved localization and reduced a number of microphones needed in a product while also reducing an amount of signal processing required for beamforming. In addition, the microphone had a smaller form factor and could fit within a small electronics package. This microphone, however, could only resolve pressure and a single axis of pressure gradient. Therefore, further improvements are desired.

Embodiments described herein provide systems and mechanisms for a microphone to resolve pressure and multiple components of pressure gradient. For example, such a microphone can include four outward-facing cantilevers anchored at a center (or center region and/or common center region) and sharing a common backside cavity. The outward-facing cantilevers can be deformable elements, e.g., each outward-facing cantilever can be deformable under pressure (e.g., such as sound pressure). In some instances, the center (or center region/common center region) can be supported by beams etched into a bulk silicon wafer. In some instances, an outward-facing cantilever (e.g., deformable element) can be triangular in shape. In addition, vibration modes of the outward-facing cantilevers can be coupled. For example, a first vibration mode can be associated with a uniform movement of all outward-facing cantilevers, e.g., responsive to a uniform pressure. As another example, a second vibration mode can be associated with out-of-phase movements among the outward-facing cantilevers, e.g., responsive to a pressure gradient. In some instances, deformation of each outward-facing cantilever (e.g., each deformable element) can be detected via a sensing material (e.g., such as a piezoelectric material) in contact with each outward-facing cantilever, e.g., to form a sensing port. In some instances, the microphone can include multiple sensing ports (e.g., each outward-facing cantilever can have or form a sensing port via contact with the sensing material). In some instances, signals from at least two sensing ports can be subtracted using analog or digital electronics to yield a signal responsive primarily to a pressure gradient along an axis. Further, in some instances, the microphone can include circuitry (e.g., such as an Application Specific Integrated Circuit (ASIC) or Field Programmable Gate Array (FPGA)) configured to post processing signals (e.g., as analog or digital signals) from the sensing ports. The post processing of the signals can include arithmetic operations to derive alternative or additional output signals from the microphone. In addition, in some instances, the signals from the sensing ports can be used as input into a neural network. The inputs can be used by the neural network can be used to accomplish a particular task, e.g., such as enhancement of a desired signal and/or suppression of non-desired signals.

As another example, a microphone package, e.g., suitable for integration into a product, such as a user equipment device (UE), can include a first substrate that houses a microphone die and an Application Specific Integrated Circuit (ASIC). The first substrate can have a sound inlet. Further, the microphone package can include a cavity formed by a second substrate and sidewalls. In such instances, the sound inlet can allow deformable elements (e.g., outward-facing cantilevers) to be in contact with and deform under external pressure and pressure gradient from a sound field external to the microphone package. Further, signals from sensing ports, e.g., formed via a sensing material (e.g., such as a piezo electric material) in contact with the deformable elements can be routed to the ASIC, e.g., via wiring. Additionally, signals from the ASIC can be routed to the first substrate (e.g., top substrate) and/or the second substrate (e.g., bottom substrate) via wiring. Vertical Interconnect Accesses (VIAs) in the first substrate and/or the second substrate can make electrical signals available at an external surface of the microphone package. Note that unlike other common MEMS microphone packages, such a microphone package can enable sensing of pressure and pressure gradient. In addition, in some instances, the signals from the sensing ports can be used as input into a neural network. The inputs can be used by the neural network can be used to accomplish a particular task, e.g., such as enhancement of a desired signal and/or suppression of non-desired signals. The neural network, e.g., circuitry forming the neural network, can be integrated into the microphone package, at least in some instances.

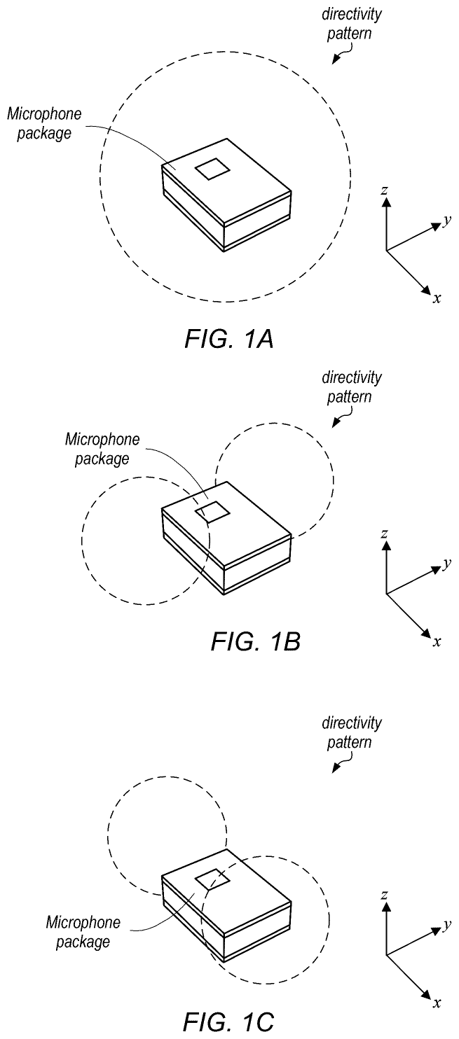

FIGS. 1A-1C illustrate examples of a packaged microphone, according to some embodiments. The packaged microphone, at least in some instances, can include a MEMS microphone configured to capture 3 measurands (e.g., P₀, dp/dx, dp/dy). As shown in FIG. 1A, the packaged microphone can have an omnidirectional pattern associated with measurement of pressure. As shown in FIG. 1B, the packaged microphone can also have a “y axis” dipole directivity associated with dp/dy. Further, as shown in FIG. 1C, the packaged microphone can also have a “x-axis” dipole directivity associated with dp/dx. Thus, in some instances, multiple measurands from a single microphone can be used as inputs to a machine learning network and/or Neural Network to accomplish a particular task, such as enhancement of a desired signal and/or suppression of non-desired signals. Such a microphone can be comprised in a limited aperture device (e.g., such as a wearable device (e.g., smartwatch), a UE, and/or wearable speakers/headphones). In some instances, the packaged microphone can function as both an omni and directional microphone, e.g., in-plane directivity can be steerable using signal processing. Such a microphone can be comprised on a single chip, at least in some instances.

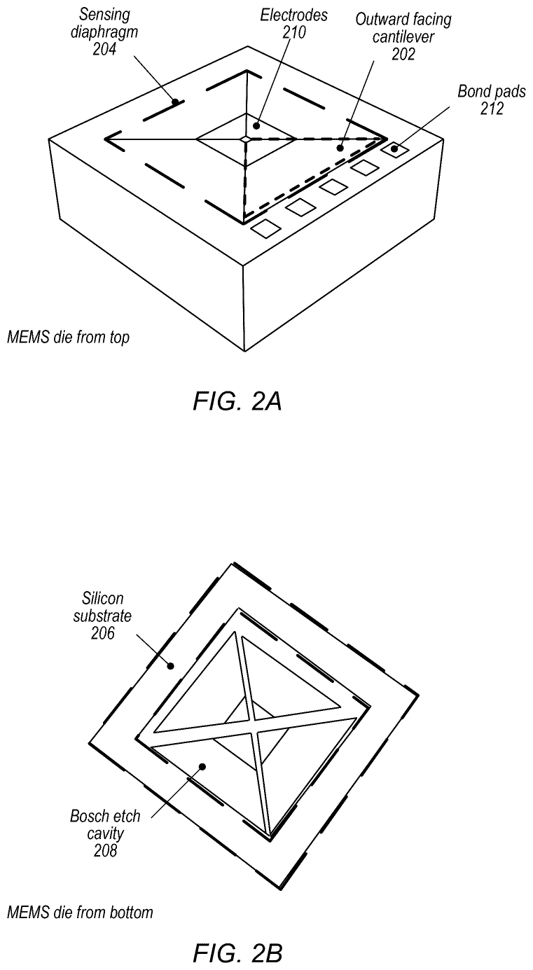

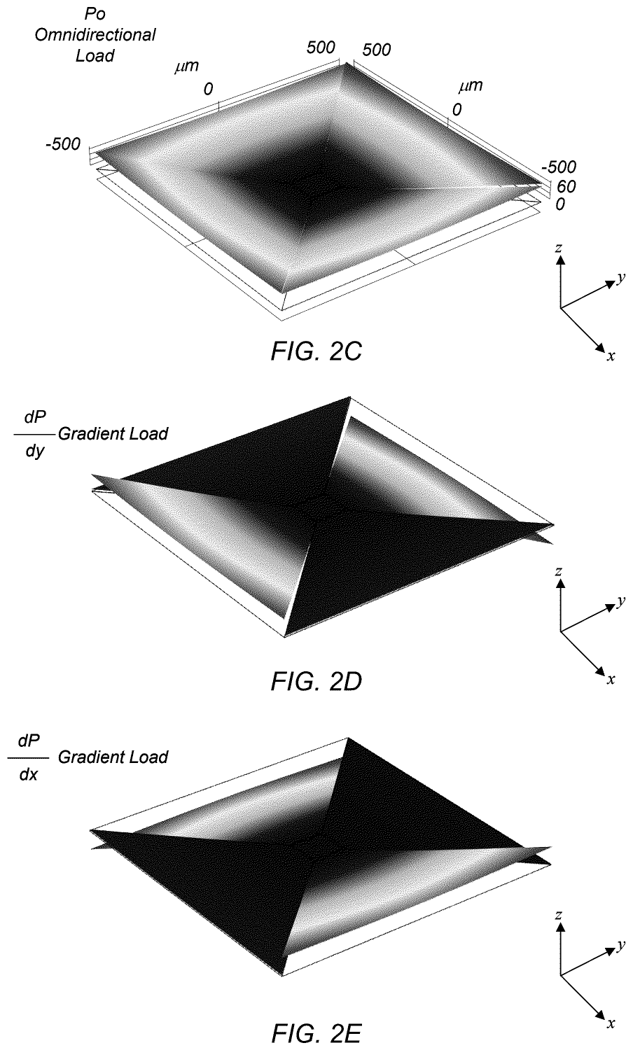

FIGS. 2A-2B illustrate an example of a MEMS microphone, according to some embodiments. In particular, FIG. 2A illustrates a top view of the MEMS microphone and FIG. 2B illustrates a bottom view of the MEMS microphone. As shown, in some instances, the MEMS microphone can include four outward facing cantilevers 202 (e.g., deformable elements). The outward facing cantilevers 202 can be mechanically coupled to yield bending and rocking mode shapes (e.g., coupled modes of vibration). In some instances, there can be high compliance of rocking modes for high signal to noise ratio (SNR) in plane directivity. In addition, as shown, the MEMS microphone can include four independent outputs from four distinct sensing regions (e.g., sensing diaphragm 204) on the structure. The sensing regions can comprise sensing material, such as piezoelectric material. In some instances, the piezoelectric material can be aluminum scandium nitride (AlScN). Further, silicon substrate 206 can include a bosch etch cavity 208. The MEMS microphone can also include electrodes 210 and bond pads 212, as shown.

FIGS. 2C-2E illustrate examples of mode shapes of a MEMS microphone, such as the MEMS microphone illustrated in FIGS. 2A and 2B. according to some embodiments. In particular, FIG. 2C illustrates an example of a deformation of a MEMS microphone structure in response to a pressure, P₀ e.g., an omnidirectional loading comprising uniform pressure on all cantilevers of the MEMS microphone. FIG. 2D illustrates an example of a deformation of a MEMS microphone structure in response to a spatial gradient in pressure along a y-axis (e.g., dp/dy). FIG. 2E illustrates an example of a deformation of a MEMS microphone structure in response to a spatial gradient in pressure along an x-axis (e.g., dp/dx).

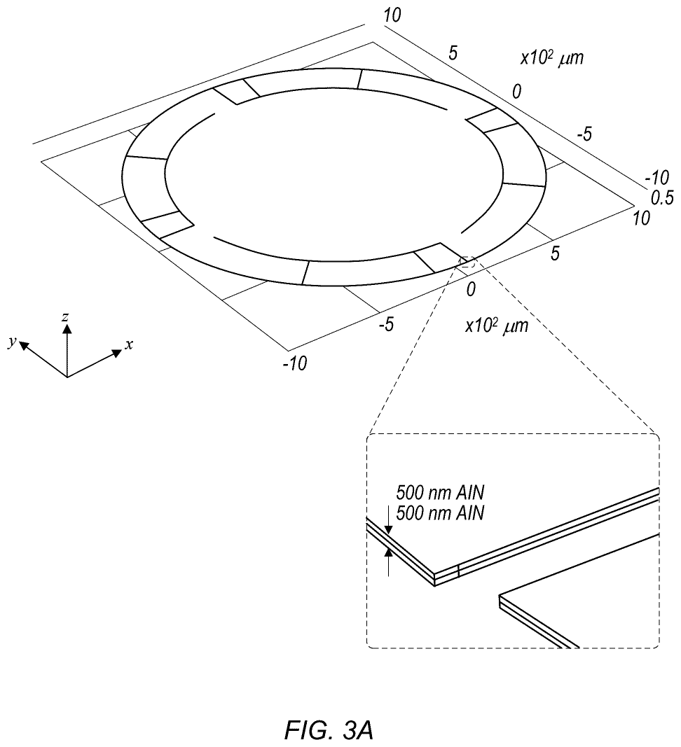

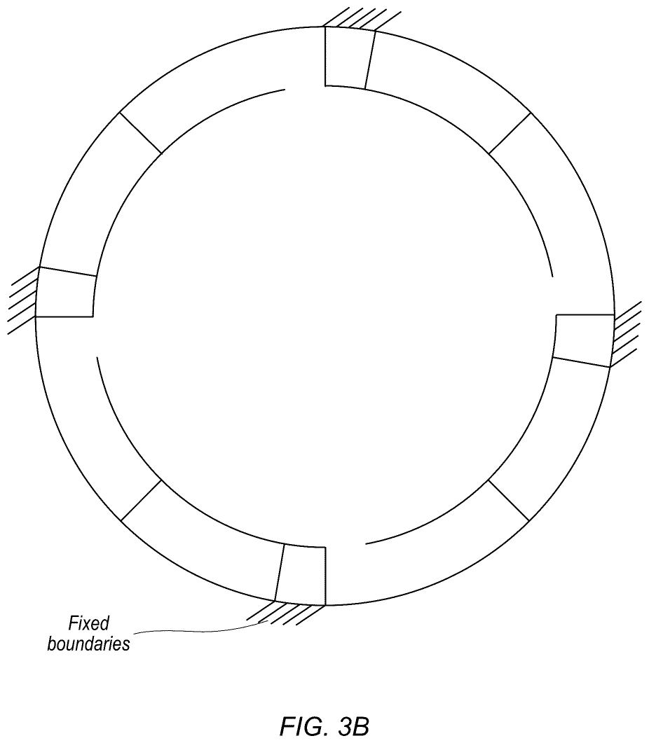

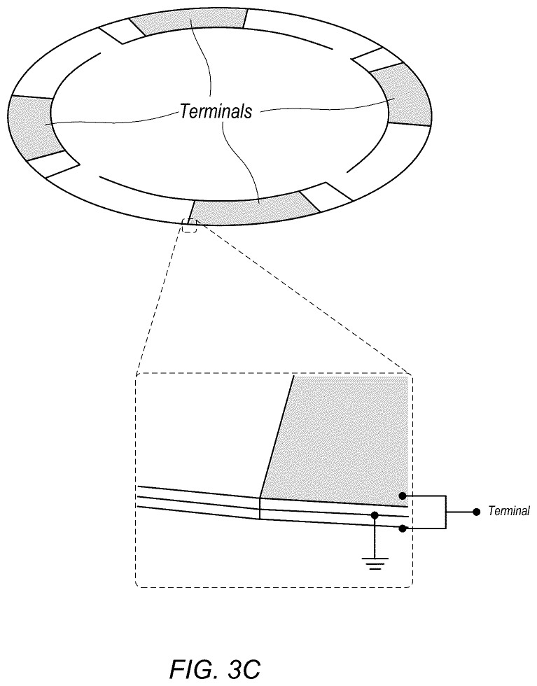

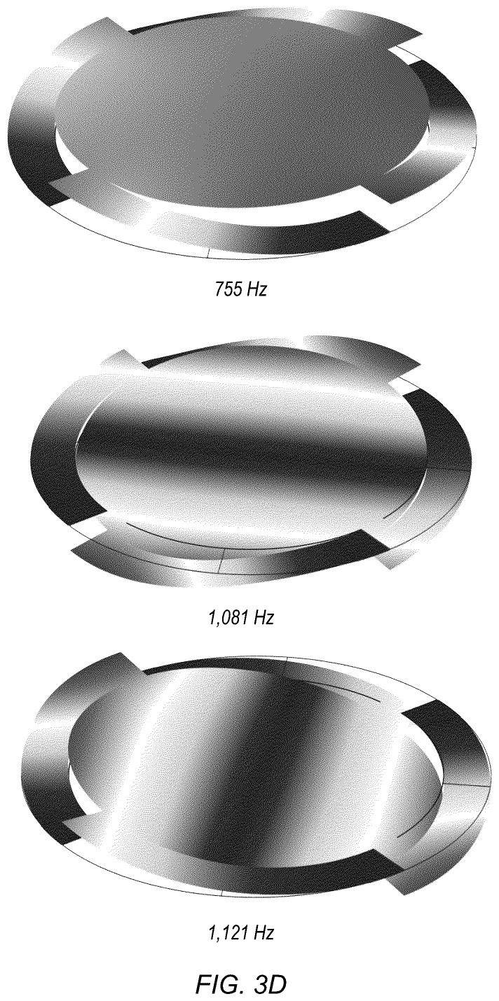

FIGS. 3A-3D illustrate another example of a MEMS microphone, according to some embodiments. In particular, FIG. 3A illustrates an aluminum nitride based MEMS microphone. As shown, the MEMS microphone can be formed using multiple layers with a total thickness of 1,000 nanometers (nm). FIG. 2A illustrates a top view of the MEMS microphone and FIG. 2B illustrates a bottom view of the MEMS microphone. As shown, in FIG. 3B, the MEMS microphone can be circular in shape with 4 cantilever sections (deformable elements) running along an outer diameter of the MEMS microphone. In addition, as shown in FIG. 3C, terminals, e.g., electrodes can be placed on each cantilever section. FIG. 3D illustrates mode shapes of the MEMS microphone, with resonant frequencies at 755 Hertz (Hz), 1,081 Hz, and 1,121 Hz, at least in some instances.

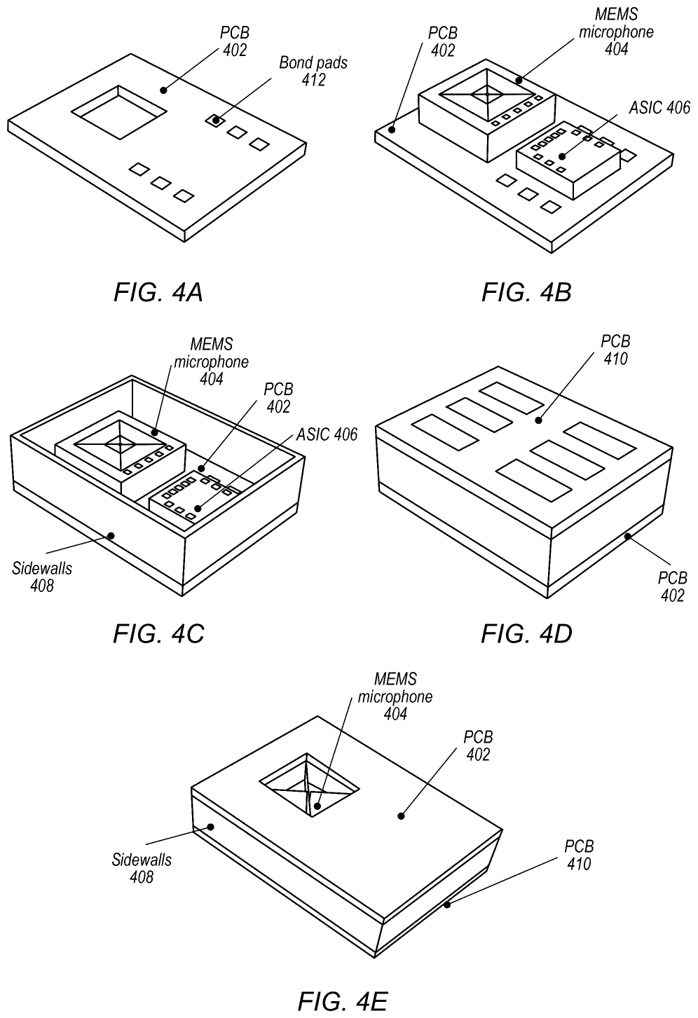

FIGS. 4A-E illustrate examples of components and assemblies of a microphone package, according to some embodiments. As shown, FIG. 4A illustrates an example of a printed circuit board (PCB) 402 with an inlet hole and contacts to receive wire-bonds (bond pads 412). This PCB 402 can be configured as a “bottom” substrate of the microphone package. FIG. 4B illustrates an example of a PCB, such as the PCB 402 illustrated in FIG. 4A, with a MEMS microphone die 404 and ASIC 406 mounted on it. The MEMS microphone die 404 can be a MEMS microphone as described above in reference to FIGS. 3A-C. FIG. 4C illustrates side walls 408 mounted on a PCB, such as the PCB 402 illustrated in FIG. 4B. FIG. 4D illustrates another PCB 410 mounted on “top” of the assembly illustrated in FIG. 4C, e.g., a “top” substrate. FIG. 4E illustrates the assembly illustrated in FIG. 4D from a “bottom” view. Note that such a package can allow an end user or customer to mount the microphone package onto their PCB board with the inlet hole facing upwards.

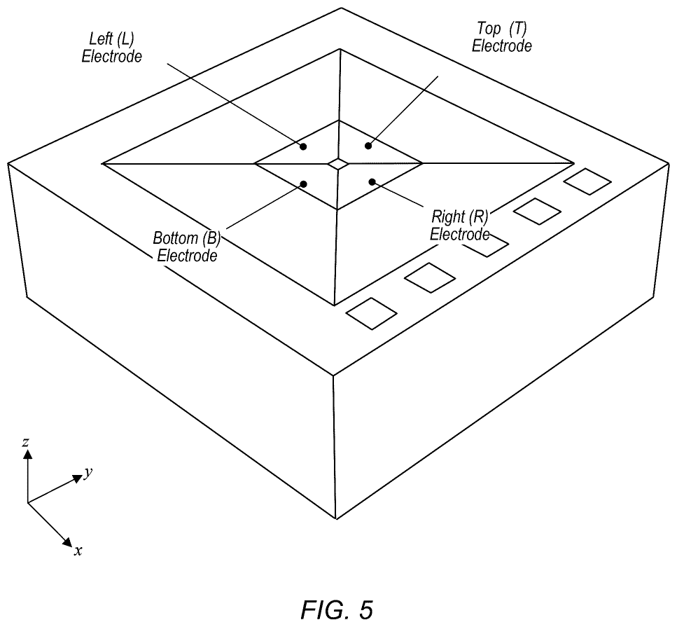

FIG. 5 illustrates an example of a MEMS microphone, according to some embodiments. Note that the MEMS microphone illustrated in FIG. 5 may be similar to and/or the same as the MEMS microphones described above. As shown, the MEMS microphone can include four electrodes, e.g., a left (L) (or first) electrode, a right (R) (or second) electrode, a top (T) (or third) electrode, and a bottom (B) (or fourth) electrode. In some instances, signals from the electrodes can undergo arithmetic operations using analog or digital electronics to yield signals proportional to an omnidirectional pressure, P₀, a gradient pressure along an x-axis, dp/dx, and/or a gradient pressure along a y-axis, dp/dy. For example, subtraction of a signal from the left electrode from the right electrode can yield a signal proportional to dp/dx. As another example, subtraction of a signal from the bottom electrode from the top electrode can yield a signal proportional to dp/dy. As a further example, summing the signals from the top, bottom, left, and right electrodes can yield a signal proportional to pressure, P₀.

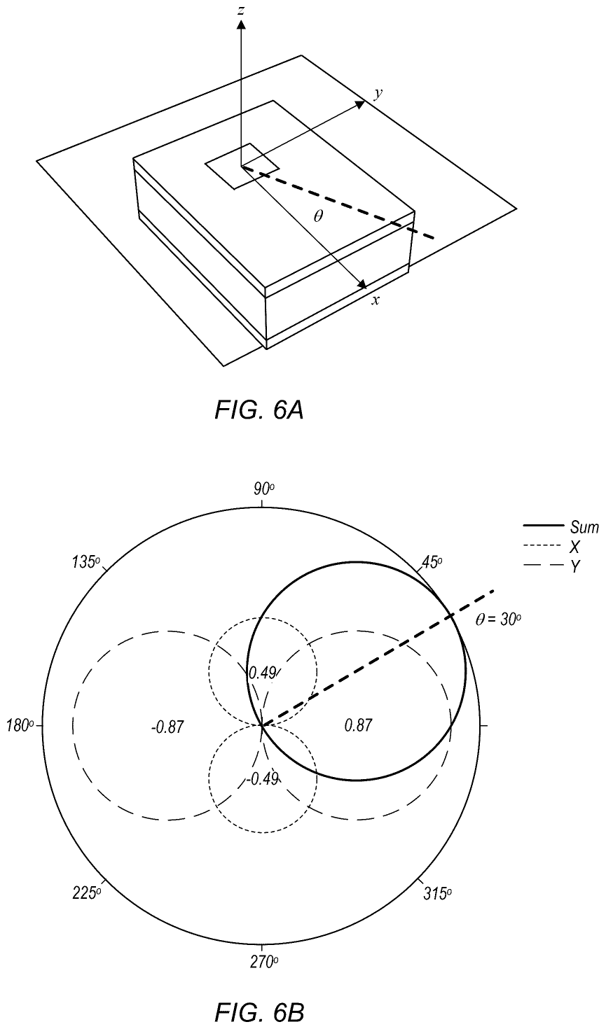

FIGS. 6A-6B illustrate another example of a microphone package, according to some embodiments. Note that microphone package illustrated in FIGS. 6A-B may be similar to or the same as the microphone packages described above. In some instances, the microphone package illustrated in FIGS. 6A-B can include a MEMS microphone as described above. In some instances, as shown in FIG. 6B, gradient signals, e.g., as derived in a manner as described above in reference to FIG. 5, can undergo further arithmetic operations to steer and/or create directivity patterns. For example, as shown an in-plane directivity at θ=30 degrees can be derived using equation (1):

$$θ = 0.87 \frac{\partial p}{\partial x} + 0.49 \frac{\partial p}{\partial y} \qquad ( 1 )$$

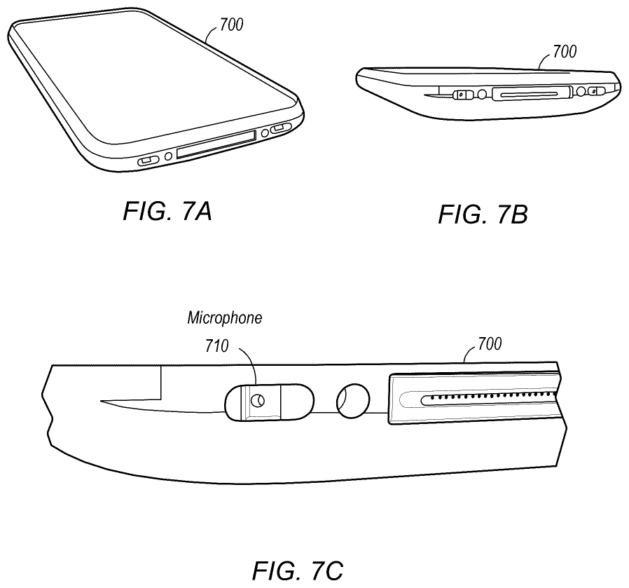

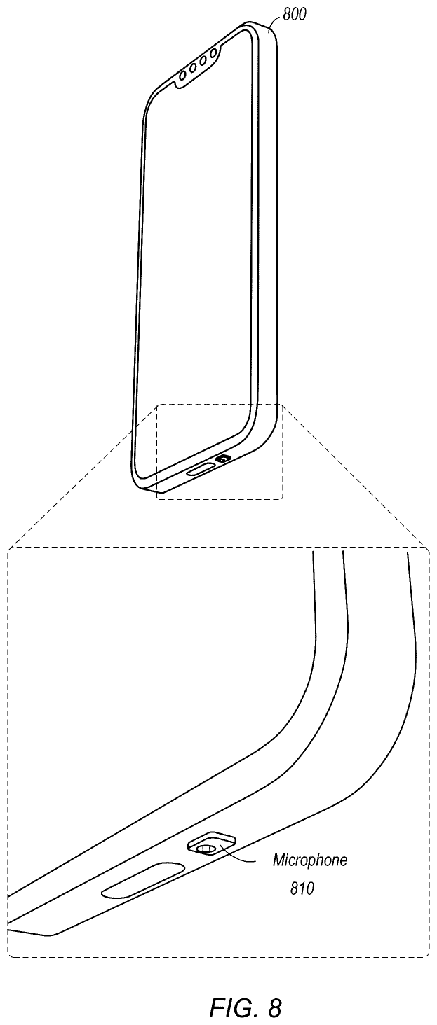

FIGS. 7A-7C illustrate an example of a user equipment device (UE) 700 which can include embodiments of the invention. Note that although UE 700 is illustrated as a cellular phone, the term UE is not limited to cellular phone. The term is intended to refer to any of various types of computer systems devices which are mobile or portable and which performs wireless communications. As shown, UE 700 may include one or more directional microphones 710 which may include embodiments of the invention. In some embodiments, no modification to the UE 700 may be necessary.

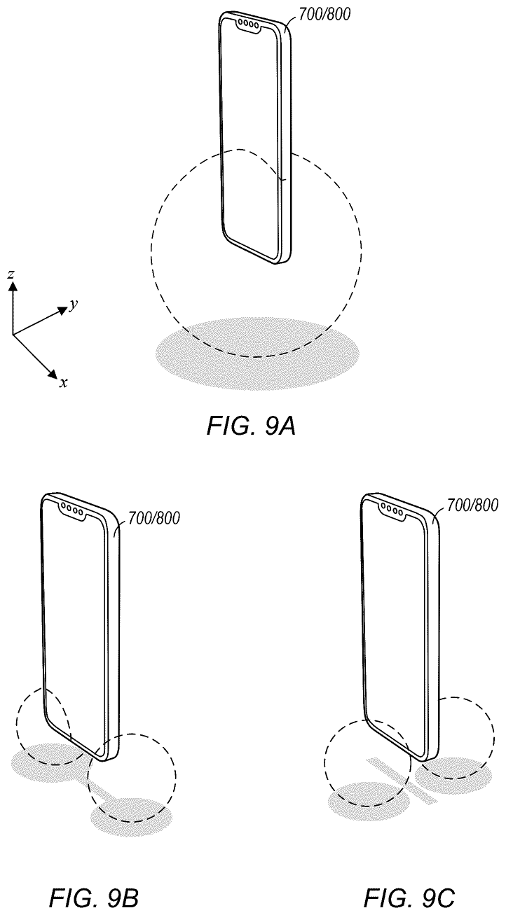

FIG. 8 illustrates another example of a user equipment device (UE) 800 which can include embodiments of the invention. As noted above, although UE 800 is illustrated as a cellular phone, the term UE is not limited to cellular phone. As shown, UE 800 may include one or more directional microphones 810 which may include embodiments of the invention. In particular, as illustrated, in FIG. 8, the one or more directional microphones 810 can be place on an exterior surface of the UE, e.g., such as on an exterior surface considered a “bottom” of the UE. Such placement can allow the directionality of the one or more directional microphones to be fully realized, e.g., as further illustrated in FIGS. 9A-9C, 10, and 11.

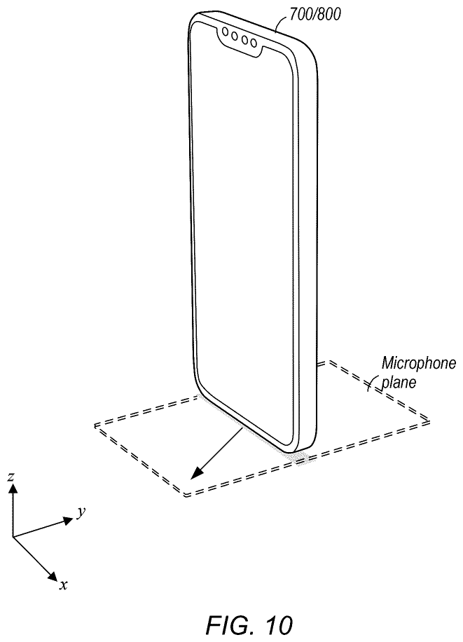

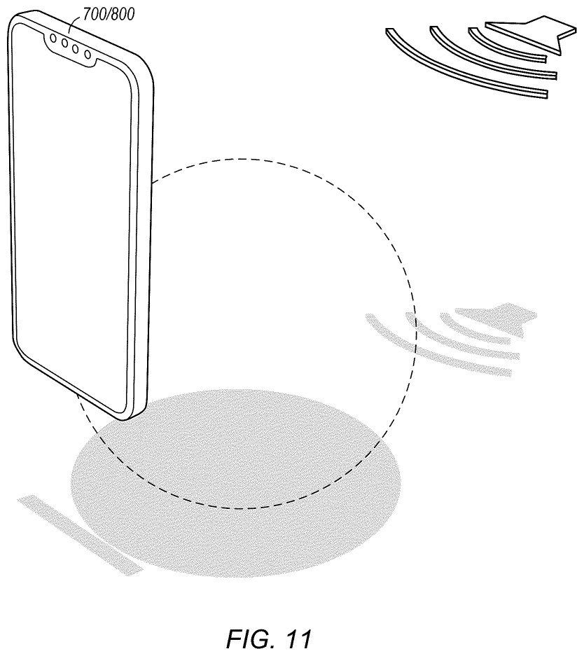

FIGS. 9A-9C and 10 illustrate examples of various configurations of UE with a MEMS microphone, according to some embodiments. As shown, a UE, such as UE 700 or UE 800, can include one or more directional microphones, e.g. such as direction microphones 710/810. The one or more directional microphones can be configured as omnidirectional microphones, e.g., as shown in FIG. 9A, “x” directional microphones, e.g., as shown in FIG. 9B, and/or as “y” directional microphones, e.g., as shown in FIG. 9C. As shown in FIG. 10, the one or more directional microphones can be configured at any arbitrary direction in a plane of the one or more directional microphones. In other words, within a microphone plane, the one or more directional microphones can be configured to receive sound waves from a particular direction within the microphone plane. Further, the microphone plane can be substantially normal to a display of the UE and/or substantially normal to a plane housing a camera of the UE. Additionally, as illustrated in FIG. 11, the one or more directional microphones can be configured to “zoom” in a particular direction, e.g., such as to pick up sound from a long distance when taking video via a camera. In other words, the one or more directional microphones can be configured with an audio zoom functionality. Said another way, the one or more directional microphones can be configured to use received signals to steer a first order directivity pattern in a microphone plane substantially parallel to a field of view of a camera of the UE.

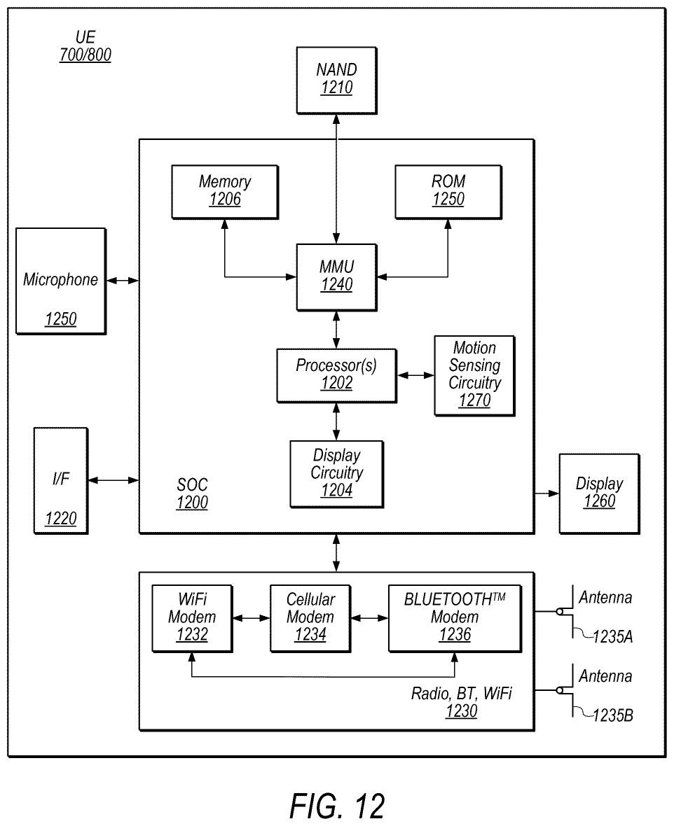

FIG. 12 illustrates an example block diagram of a wireless device, such as UE 700 and/or UE 800, according to some embodiments. In some instances, the UE can additionally or alternatively be referred to as a wireless station (“STA”). As shown, the UE 700/800 can include a system on chip (SOC) 1200, which can include one or more portions configured for various purposes. Some or all of the various illustrated components (and/or other device components not illustrated, e.g., in variations and alternative arrangements) can be “communicatively coupled” or “operatively coupled,” which terms can be taken herein to mean components that can communicate, directly or indirectly, when the device is in operation.

As shown, the SOC 1200 can include processor(s) 1202, which can execute program instructions for the UE 700/800, and display circuitry 1204, which can perform graphics processing and provide display signals to the display 1260. The SOC 200 can also include motion sensing circuitry 1270, which can detect motion of the UE 700/800 in one or more dimensions, for example using a gyroscope, accelerometer, and/or any of various other motion sensing components. The processor(s) 1202 can also be coupled to memory management unit (MMU) 1240, which can be configured to receive addresses from the processor(s) 1202 and translate those addresses to locations in memory (e.g., memory 1206, read only memory (ROM) 1250, flash memory/NAND 1210). The MMU 1240 can be configured to perform memory protection and page table translation or set up. In some instances, the MMU 1240 can be included as a portion of the processor(s) 1202.

As shown, the SOC 1200 can be coupled to various other circuits of the UE 700/800. For example, the UE 700/800 can include various types of memory (e.g., including flash memory/NAND 1210), a connector interface 1220 (e.g., for coupling to a computer system, dock, charging station, etc.), the display 1260, one or more microphones 1250 and wireless communication circuitry 1230 (e.g., for LTE, LTE-A, 5G NR, 6G, Bluetooth, Wi-Fi, NFC, GPS, UWB, peer-to-peer (P2P), device-to-device (D2D), etc.).

The UE 700/800 can include at least one antenna, and in some instances can include multiple antennas, e.g., 1235A and 1235B, for performing wireless communication with access points, base stations, wireless stations, and/or other devices. For example, the UE 700/800 can use antennas 1235A and 1235B to perform the wireless communication. As noted above, the UE 700/800 can, in some examples, be configured to communicate wirelessly using a plurality of wireless communication standards or radio access technologies (RATs).

The wireless communication circuitry 1230 can include a Wi-Fi modem 1232, a cellular modem 1234, and a Bluetooth modem 1236. The Wi-Fi modem 1232 is for enabling the UE 700/800 to perform Wi-Fi or other WLAN communications, e.g., on an 802.11 network. The Bluetooth modem 1236 is for enabling the UE 700/800 to perform Bluetooth communications. The cellular modem 1234 can be capable of performing cellular communication according to one or more cellular communication technologies, e.g., in accordance with one or more 3GPP specifications.

As described herein, UE 700/800 can include hardware and software components for implementing aspects of this disclosure, e.g., by a processor executing program instructions stored on a memory medium (e.g., a non-transitory computer-readable memory medium), a processor configured as an FPGA (Field Programmable Gate Array), and/or using dedicated hardware components, which can include an ASIC (Application Specific Integrated Circuit).

In addition, the one or more microphones 1250 can include one or more directional microphones, such as microphones 710 and/or 810. Thus, the one or microphones 1250 can be a MEMS microphone as described herein, e.g., such as the MEMS microphones described in reference to the above Figures.

For example, in at least some instances, at least one of the one or more microphones 1250 can include at least two elements configured to deform under pressure and at least two sensing ports corresponding to the at least two elements. Further, a first vibration mode of the at least two elements cam be associated with uniform movements of the at least two elements and a second vibration mode of the at least two elements can be associated with out-of-phase movements of the at least two elements. Additionally, signals from the at least two sensing ports can be subtracted to yield a signal responsive primarily to a pressure gradient along an axis of the at least one microphone. In some examples, the at least two elements can be anchored at a center region and the at least two elements can be at least two cantilever elements. In some examples the at least two elements can be triangular in shape. In some examples, the at least two sensing ports can include sensing material in contact with the at least two elements. The sensing material can be a piezoelectric material. In some examples, the at least two elements can share a common backside cavity. Further, in some examples, the at least two elements can be four elements and the at least two sensing ports can be four sensing ports. In some further examples, the at least one microphone can also include circuitry configured to subtract signals from the at least two sensing ports to yield a signal responsive primarily to a pressure gradient along an axis of the at least one microphone. In further examples, the at least one microphone can include circuitry configured to perform arithmetic operations on the signals from the at least two sensing ports to derive alternative or additional output signals from the microphone. In some examples, the signals can be input signals to a neural network. The neural network can be included in the at least one microphone and the input signals can be input into the neural network to enhance a desired signal, to suppress one or more non-desired signals, and/or to train the neural network.

As another example, in at least some instances, the at least one of the one or more microphones 1250 can include a microphone package. The microphone package can include a first substrate, a second substrate, and sidewalls. The second substrate and the sidewalls can be positioned to form a cavity. The first substrate can include a microphone die, an Application Specific Integrated Circuit (ASIC), and a sound inlet. The microphone die can include at least two elements configured to deform under pressure and at least two sensing ports corresponding to the at least two elements. Further, a first vibration mode of the at least two elements cam be associated with uniform movements of the at least two elements and a second vibration mode of the at least two elements can be associated with out-of-phase movements of the at least two elements. Additionally, signals from the at least two sensing ports can be subtracted to yield a signal responsive primarily to a pressure gradient along an axis of the at least one microphone. In some examples, the sound inlet can be configured to allow the at least two elements to be in contact with and deform under external pressure and pressure gradient from a sound field external to the microphone package. In some examples, the signals from the at least two sensing ports can be routed to the ASIC and the ASIC can be configured to subtract signals from the at least two sensing ports to yield a signal responsive primarily to a pressure gradient along an axis and/or to perform arithmetic operations on the signals from the at least two sensing ports to derive alternative or additional output signals. In some examples, the signals outputted from the ASIC can be routed to one or more Vertical Interconnect Accesses (VIAs) for availability at an external surface of the microphone package. The one or VIAs can be included one or more of the first substrate or the second substrate. Further, in some examples, the ASIC can be a neural network or can be configured as a neural network and the signals from the at least two sensing ports can be input signals to the neural network. In such examples, the neural network can be configured to consume the input signals from the at least two sensing ports to enhance a desired signal, to suppress one or more non-desired signals, and/or to train the neural network. In some examples, the at least two elements can be anchored at a center region and the at least two elements can be at least two cantilever elements. In some examples the at least two elements can be triangular in shape. In some examples, the at least two sensing ports can include sensing material in contact with the at least two elements. The sensing material can be a piezoelectric material. In some examples, the at least two elements can share the cavity. Further, in some examples, the at least two elements can be four elements and the at least two sensing ports can be four sensing ports.

Further, in some instances, the pressure gradient can include a first gradient along a first axis and a second gradient along a second axis that form a microphone plane along the axis. In such instances, the microphone plane can be substantially parallel to an exterior surface of the UE. For example, the microphone plane can be substantially parallel to a bottom surface of the UE. In addition, the microphone plane can be substantially normal to a display of the UE and/or to a plane housing a camera of the UE. In some instances, the circuitry can be configured to steer a first order directivity pattern using the signals. In such instances, the microphone plane can be substantially parallel to a field of view of a camera of the UE. In some instances, the microphone plane is offset in a vertical direction substantially perpendicular to the exterior surface. In some instances, at least the at least two elements of the microphone can be mounted such that the at least two elements are in a plane external to the UE, e.g., in a plane adjacent to at least one side of the UE, e.g., such as affixed to an external surface of the UE. As an example, the microphone package can be affixed to an external surface of the UE and/or the microphone package can be mounted to the UE such that the at least two elements are in a plane external to the UE.

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A microphone, comprising:
at least two elements configured to deform under pressure, wherein a first vibration mode of the at least two elements is associated with uniform movements of the at least two elements, and wherein a second vibration mode of the at least two elements is associated with out-of-phase movements of the at least two elements; and
at least two sensing ports corresponding to the at least two elements, wherein signals from the at least two sensing ports can be subtracted to yield a signal responsive primarily to a pressure gradient along an axis.

2. The microphone of claim 1,
wherein the at least two elements are anchored at a center region.

3. The microphone of claim 2,
wherein the at least two elements comprise at least two cantilever elements.

4. The microphone of claim 1,
wherein the at least two sensing ports comprise sensing material in contact with the at least two elements.

5. The microphone of claim 4,
wherein the sensing material comprises a piezoelectric material.

6. The microphone of claim 1,
wherein the at least two elements share a common backside cavity.

7. The microphone of claim 1,
wherein the at least two elements comprise four elements; and
wherein the at least two sensing ports comprise four sensing ports.

8. The microphone of claim 1, further comprising:
circuitry configured to:
subtract signals from the at least two sensing ports to yield a signal responsive primarily to a pressure gradient along an axis; and
derive alternative or additional output signals from the microphone.

9. The microphone of claim 1,
wherein the signals are input signals to neural network, wherein the microphone further comprises the neural network, and wherein the input signals are input into the neural network to enhance a desired signal, to suppress one or more non-desired signals, or to train the neural network.

10. A microphone package, comprising:
a first substrate, comprising:
a microphone die, comprising:
at least two elements configured to deform under pressure, wherein a first vibration mode of the at least two elements is associated with uniform movements of the at least two elements, and wherein a second vibration mode of the at least two elements is associated with out-of-phase movements of the at least two elements; and
at least two sensing ports corresponding to the at least two elements, wherein signals from the at least two sensing ports can be subtracted to yield a signal responsive primarily to a pressure gradient along an axis;
an Application Specific Integrated Circuit (ASIC); and
a sound inlet;
a second substrate; and
sidewalls; and
wherein the second substrate and sidewalls form a cavity.

11. The microphone package of claim 10,
wherein the sound inlet is configured to allow the at least two elements to be in contact with and deform under external pressure and pressure gradient from a sound field external to the microphone package.

12. The microphone package of claim 10,
wherein the signals from the at least two sensing ports are routed to the ASIC; and
wherein the ASIC is configured to:
subtract signals from the at least two sensing ports to yield a signal responsive primarily to a pressure gradient along an axis; and
perform arithmetic operations on the signals from the at least two sensing ports to derive alternative or additional output signals.

13. The microphone package of claim 10,
wherein signals outputted from the ASIC are routed to one or more Vertical Interconnect Accesses (VIAs) for availability at an external surface of the microphone package.

14. The microphone package of claim 10,
wherein the ASIC comprises or is configured as a neural network;
wherein the signals from the at least two sensing ports are input signals to the neural network; and
wherein the neural network is configured to consume the input signals from the at least two sensing ports to enhance a desired signal, suppress one or more non-desired signals, or the neural network.

15. A user equipment device (UE), comprising:
at least one directional microphone;
a memory; and
a processor in communication with the memory and the one or more direction microphones and configured to digitally processes signals produced from the one at least one directional microphone, wherein the at least one directional microphone comprises:
at least two elements configured to deform under pressure, wherein a first vibration mode of the at least two elements is associated with uniform movements of the at least two elements, and wherein a second vibration mode of the at least two elements is associated with out-of-phase movements of the at least two elements; and
at least two sensing ports corresponding to the at least two elements, wherein signals from the at least two sensing ports can be subtracted to yield a signal responsive primarily to a pressure gradient along an axis.

16. The UE of claim 15,
wherein the pressure gradient comprises a first gradient along a first axis and a second gradient along a second axis that form a microphone plane along the axis and substantially parallel to an exterior surface of the UE.

17. The UE of claim 16,
wherein the microphone plane is substantially normal to a display of the UE or to a plane housing a camera of the UE.

18. The UE of claim 16,
wherein the at least one directional microphone further comprises circuitry configured to steer a first order directivity pattern using the signals.

19. The UE of claim 18,
wherein the microphone plane is substantially parallel to a field of view of a camera of the UE.

20. The UE of claim 16,
wherein the microphone plane is offset in a vertical direction substantially perpendicular to the exterior surface.
